(19) United States
(12) Patent Application Publication
(10) Pub. No.: US 2024/0096855 A1
(43) Pub. Date: Mar. 21, 2024

(54) WAFER-LEVEL MANUFACTURE OF OPTICAL PACKAGES

(71) Applicant: ams-OSRAM Asia Pacific Pte. Ltd., Singapore (SG)

(72) Inventors: Zhen Kai NAM, Singapore (SG); Qi Chuan YU, Singapore (SG); Kam Wah LEONG, Singapore (SG); Yeu Woon CHAN, Singapore (SG); Royce VIRINTHORN, Singapore (SG); Sundar Raman GNANA SAMBANDAM, Singapore (SG); Zhang Xin SUN, Singapore (SG)

(73) Assignee: ams-OSRAM Asia Pacific Pte. Ltd., Singapore (SG)

(21) Appl. No.: 18/256,910

(22) PCT Filed: Dec. 8, 2021
(86) PCT No.: PCT/SG2021/050768

§ 371 Date: Jun. 9, 2023

(30) Foreign Application Priority Data
Dec. 14, 2020 (GB) 2019666.3

(51) Int. Cl. H01L 25/075; H01L 33/58

(52) U.S. Cl. CPC H01L 25/0753; H01L 33/58; H01L 2933/0058

(57) ABSTRACT

A method of wafer-level manufacturing of an optical package (285) is disclosed. The method comprises forming an apertured substrate (170; 405) by a process of vacuum injection molding, each aperture (175A; 175B) in the apertured substrate configured to support an optical element (225; 420; 425). The method also comprises coupling the apertured substrate to a further substrate (255) comprising optical devices (260, 265) aligned with the apertures in the apertured substrate. Also disclosed is optical package (285, 600) formed according to the method and an apparatus, such as a smartphone, comprising the optical package.

### FIELD OF INVENTION

The present disclosure relates to methods of wafer-level manufacturing of optical packages for use in optical devices, and in particular to methods of manufacturing using a vacuum injection molding process to form substrates for supporting optical elements.

### BACKGROUND TO INVENTION

Optical devices that include one or more optical radiation emitters and one or more optical sensors can be used in a wide range of applications including, for example, distance measurement, proximity sensing, gesture sensing, and imaging. Such devices may comprise complex optical packages. Assembly of such optical packages may require precision manufacturing and assembly of a multitude of individual components.

Such optical packages may not only house the radiation sensors and/or radiation emitters, but may also impart particular optical properties upon radiation propagating through the optical package.

For example, it is known that some optical packages may comprise a lens, or other optical element. In known optical packages, a substrate such as a printed circuit board laminate, may be provided with an aperture, wherein a lens or other optical element may attached to the substrate and aligned with the aperture.

However, forming apertures by drilling holes in the substrate may result in artefacts, such as burrs, which may interfere with the optical package assembly process. Such artefacts may be detrimental to manufacturing yield and cost-effectiveness. Furthermore, such artefacts may affect a quality or reliability of an assembled package.

In addition, attaching an optical element to the substrate may require adhesion or other attachment methods to be employed, thereby incurring a risk that the optical element may at least partly separate from the substrate during a lifetime of the device.

Furthermore, existing devices that are based on substrates, such as printed circuit board laminates or the like, may provide limited flexibility during a design and development phase of the optical package, and may require long lead-times to adjust any feature or size of the optical package.

Thus, it is desirable to implement a relatively low-complexity method of designing, developing, and manufacturing an optical package, wherein the method is cost-effective and provides a high manufacturing yield.

Furthermore, it is desirable that optical packages are manufactured by the method exhibit high reliability over lifetime.

It is therefore an object of at least one embodiment of at least one aspect of the present disclosure to obviate or at least mitigate at least one of the above identified shortcomings of the prior art.

### SUMMARY OF INVENTION

The present disclosure relates to methods of wafer-level manufacturing of optical packages for use in sensors, and in particular to methods of manufacturing using a vacuum injection molding process to form substrates for supporting optical elements. According to a first aspect of the disclosure, there is provided a method of wafer-level manufacturing of an optical package. The method comprises forming an apertured substrate by a process of vacuum injection molding, each aperture in the apertured substrate configured to support an optical element. The method also comprises coupling the apertured substrate to a further substrate comprising optical devices aligned with the apertures in the apertured substrate.

Advantageously, by implementing apertures in a substrate using a vacuum-injection molding process instead of drilling a prefabricated substrate, such as an FR-4 printed circuit board laminate, manufacturing artefacts such as burrs may be eliminated. Beneficially, a manufacturing yield may be increased and reliability of an assembled optical package may be improved.

Furthermore, use of a vacuum-injection molding process may advantageously increase flexibility in the design process, enabling new designs to be developed with relatively short lead times. By implementing a vacuum injection molding process, more complex shapes may be formed that would otherwise be possible by merely drilling a substrate, as described in more detail below.

The method may comprise a step of forming an optical element in each aperture by jetting or molding an epoxy into each aperture. The epoxy may be transparent to radiation emitted and/or sensed by the optical devices.

Advantageously, by jetting or molding an epoxy into each aperture an optical element may be formed that exactly fits the apertures. Furthermore, a necessity for adhesive or other techniques to couple an optical device to the substrate may be mitigated.

Advantageously, by forming an optical element such as by injecting or jetting a clear epoxy in each aperture, a strong adhesion between the optical element and the aperture may be formed.

The epoxy may be transparent to infrared radiation, e.g. near infrared radiation.

The method may further comprise a step of curing the epoxy. The step of curing the epoxy may comprise ultraviolet and/or thermal curing.

The method may further comprise a step of grinding and/or polishing the epoxy after hardening of the epoxy.

By grinding and/or polishing the epoxy, the optical element may be made flush with upper and/or lower surface of the substrate. The substrate itself may also be ground and/or polished to ensure a surface of the optical element is effectively flush with a surface of the substrate.

Advantageously, the method of grinding and/or polishing may prepare the optical element for application of at least one layer of material, as described below.

The method may comprise a step of forming at least one layer of material over the optical element.

The step of forming the at least one layer of material over the optical element may comprise spin-coating the material, spraying the material, or a process of thin-film deposition.

The at least one layer of material may be configured as: a filter, e.g. an interference filter; a polarizer; an anti-reflective coating; and/or a diffuser.

Advantageously, the optical element may act as a base upon which one or more layers of material may be formed to alter characteristics of radiation propagating through the optical element.

The step of forming at least one layer of material may comprise lithographically etching a photoresist material.

The method of may comprise adhering or forming a lens over one or both sides of the optical element.

The lens may be formed by a process of replication.

Each aperture may be formed around the optical element.

Advantageously, by forming the aperture around the optical element, the optical element may be held and/or supported relative to the optical package, thus improving a reliability of the optical package.

The optical element may be formed by vacuum injection molding a material, such as a transparent or translucent epoxy, into each aperture in the apertured substrate.

The optical element may be a diffuser.

A plurality of apertures may be arranged to form a grating. The material may be injected into all apertures forming a grating.

The apertured substrate may be formed on a portion of an upper and a lower surface of the optical element, such that the optical element is retained by the apertured substrate.

That is, the apertured substrate may be formed as a frame configured to hold the optical element. In some embodiments the apertured substrate may be formed around at least a portion of a perimeter of the optical element

Advantageously, by forming the apertured substrate relative to the optical element such that the optical element is retained by the apertured substrate, a requirement to implement adhesive or other means to couple the optical element to the substrate is mitigated. This may increase an overall cost-effectiveness of the manufacturing process. Furthermore, by forming an aperture that effectively holds or grips the optical element, a likelihood of the optical element becoming detached from the substrate in use is decreased, thus improving overall reliability of the optical package.

The apertured substrate may be formed to comprise at least one of: an optical baffle; a spacer; and/or a cap structure.

Advantageously, in some embodiments the substrate supporting the optical elements may be formed as a monolithic structure with a baffle, spacer and/or cap structure, thereby reducing an overall component count of the optical package and simplifying an assembly process.

The method may comprise at least one step of forming a further apertured substrate having apertures configured for baffles and/or spacers.

The method may comprise at least one step of adhering the further apertured substrate to the apertured substrate such that apertures in both substrates are aligned.

An adhesive may be applied to the apertured substrate by a process of screen-printing or jetting.

The method may comprise a step of singulating the apertured substrate and the further substrate after the apertured substrate has been coupled to the further substrate.

The step of singulating the apertured substrate and the further substrate may provide a plurality of optical packages. Each optical package may comprise at least one optical device. Each optical package may comprise at least one optical element.

In some embodiments, each optical package may comprise a radiation-emitting device, such as a vertical cavity surface emitting laser (VCSEL), and a sensor configured to sense radiation emitted by the radiation-emitting device.

According to a second aspect of the disclosure, there is provided an optical package formed according to the method of the first aspect.

The optical devices may comprise a device configurable to emit infrared radiation.

The optical devices may comprise a radiation-sensitive device configurable to sense infrared radiation.

According to a second aspect of the disclosure, there is provided an apparatus comprising the optical package according to the second aspect, wherein the apparatus is one of: a smartphone; a cellular telephone; a tablet; or a laptop device.

The above summary is intended to be merely exemplary and non-limiting. The disclosure includes one or more corresponding aspects, embodiments or features in isolation or in various combinations whether or not specifically stated (including claimed) in that combination or in isolation. It should be understood that features defined above in accordance with any aspect of the present disclosure or below relating to any specific embodiment of the disclosure may be utilized, either alone or in combination with any other defined feature, in any other aspect or embodiment or to form a further aspect or embodiment of the disclosure.

### BRIEF DESCRIPTION OF THE PREFERRED EMBODIMENTS

These and other aspects of the present disclosure will now be described, by way of example only, with reference to the accompanying drawings, wherein:

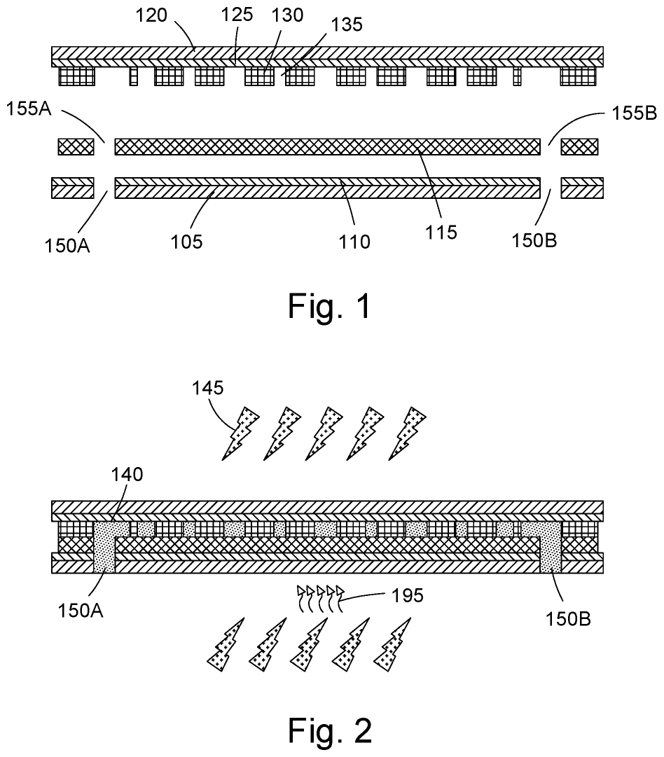

FIG. 1 depicts a representation of initial steps in a process of wafer-level manufacturing of an optical package, according to an embodiment of the disclosure;

FIG. 2 depicts a representation of further steps in the process of wafer-level manufacturing of the optical package, according to an embodiment of the disclosure;

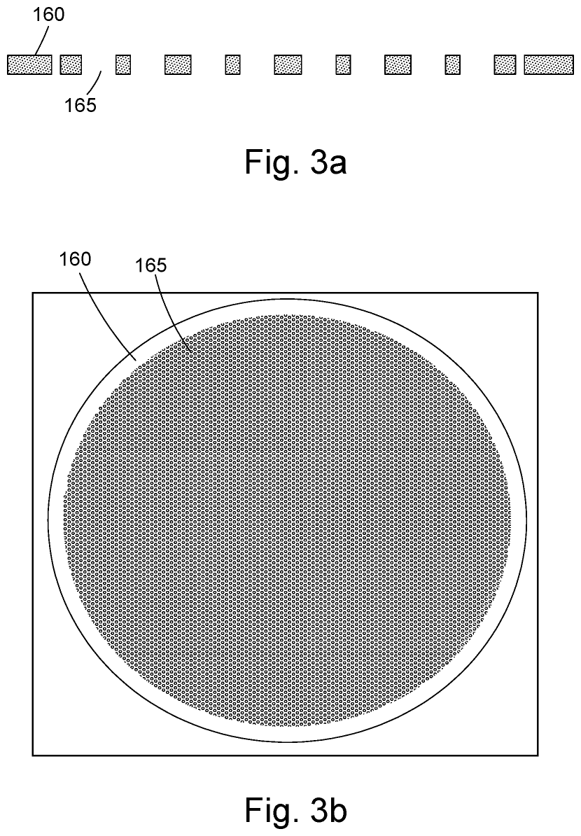

FIG. 3a depicts a cross-sectional view of an apertured substrate formed by a method according to an embodiment of the disclosure;

FIG. 3b depicts a top view of the apertured substrate of FIG. 3a;

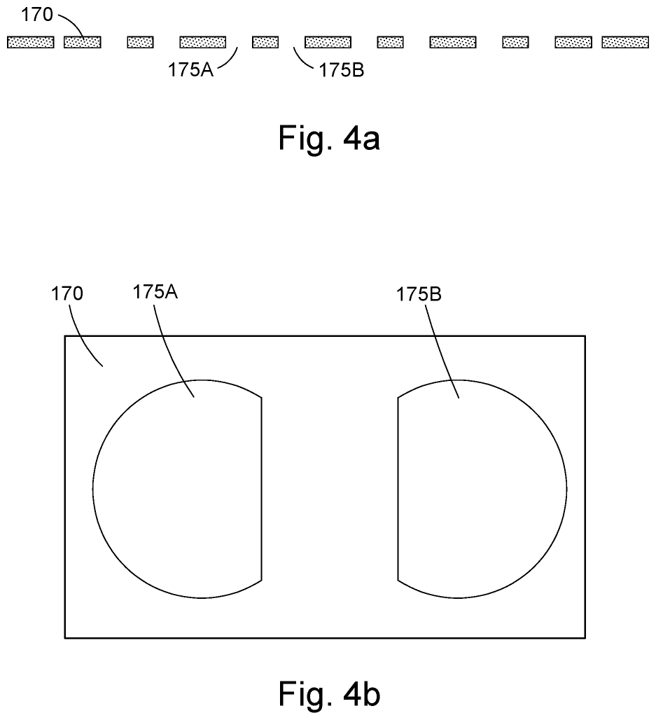

FIG. 4a depicts a cross-sectional view of a further apertured substrate formed by a method according to an embodiment of the disclosure;

FIG. 4b depicts a top view of a pair of apertures in the substrate of FIG. 4a;

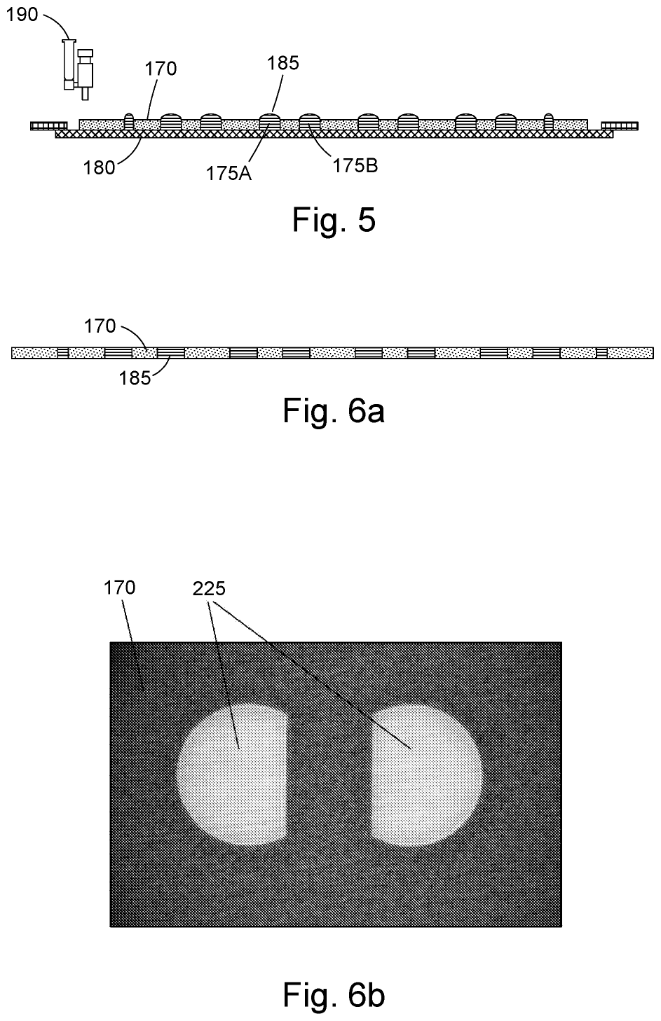

FIG. 5 depicts a representation of further steps in the process of wafer-level manufacturing of the optical package, according to an embodiment of the disclosure;

FIG. 6a depicts a cross-sectional view of an apertured substrate supporting optical elements, formed by a method according to an embodiment of the disclosure;

FIG. 6b depicts a top view of a pair of optical elements formed in the apertures of the substrate depicted in FIG. 6a;

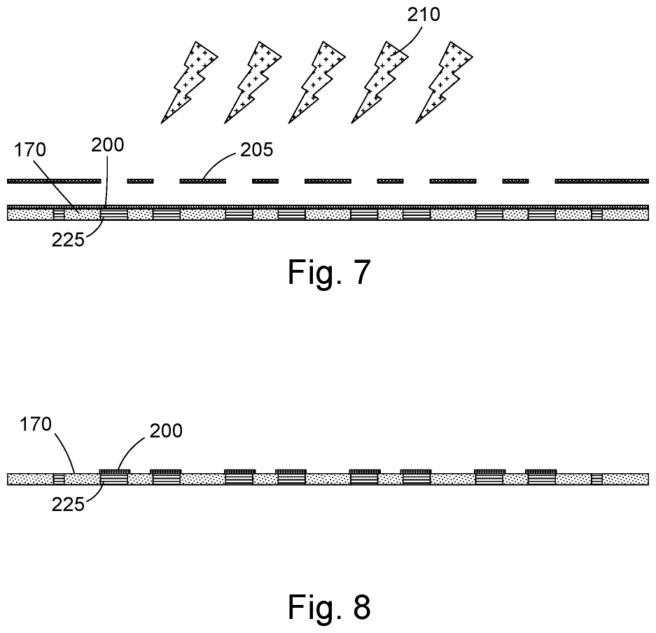

FIG. 7 depicts a representation of further steps in the process of wafer-level manufacturing of the optical package, according to an embodiment of the disclosure;

FIG. 8 depicts a cross-sectional view of an apertured substrate of FIG. 7, and having a layer of material formed over each optical element;

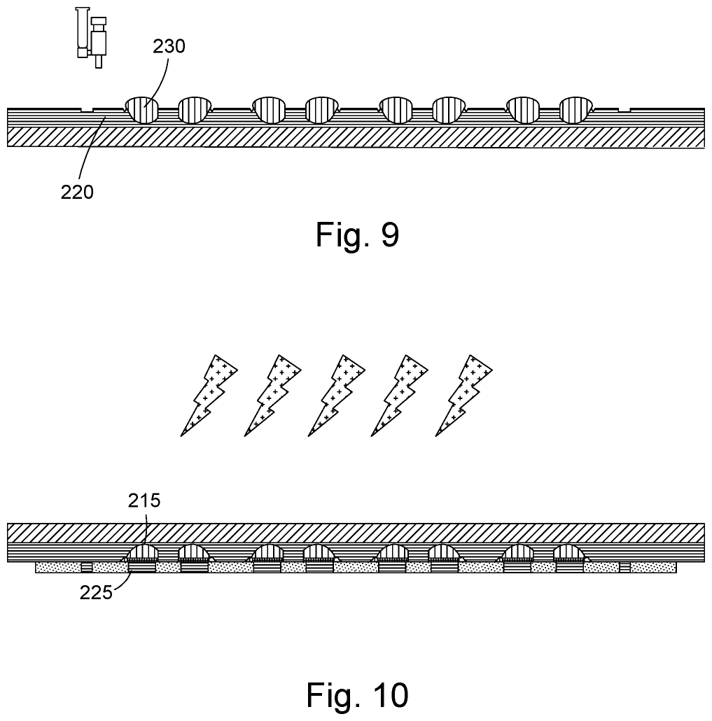

FIG. 9 depicts a representation of further steps in the process of wafer-level manufacturing of the optical package, according to an embodiment of the disclosure;

FIG. 10 depicts a representation of further steps in the process of wafer-level manufacturing of the optical package, according to an embodiment of the disclosure;

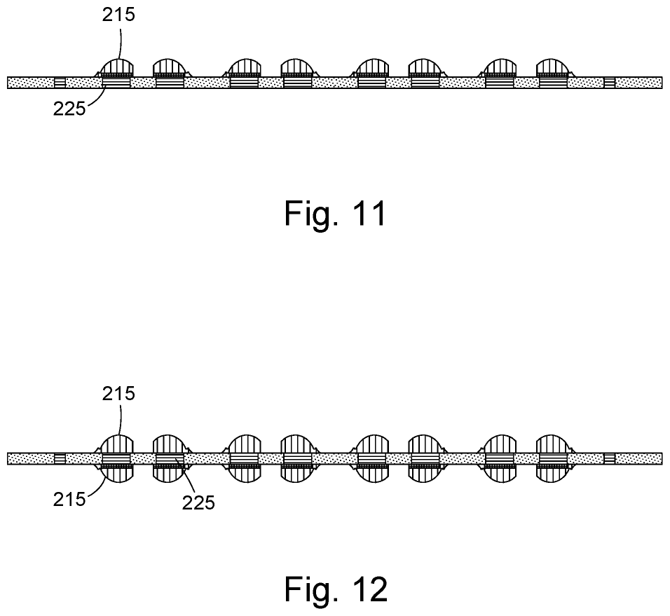

FIG. 11 depicts a cross-sectional view of an apertured substrate having lenses formed on one side of each optical element;

FIG. 12 depicts a cross-sectional view of an apertured substrate having lenses formed on both sides of each optical element;

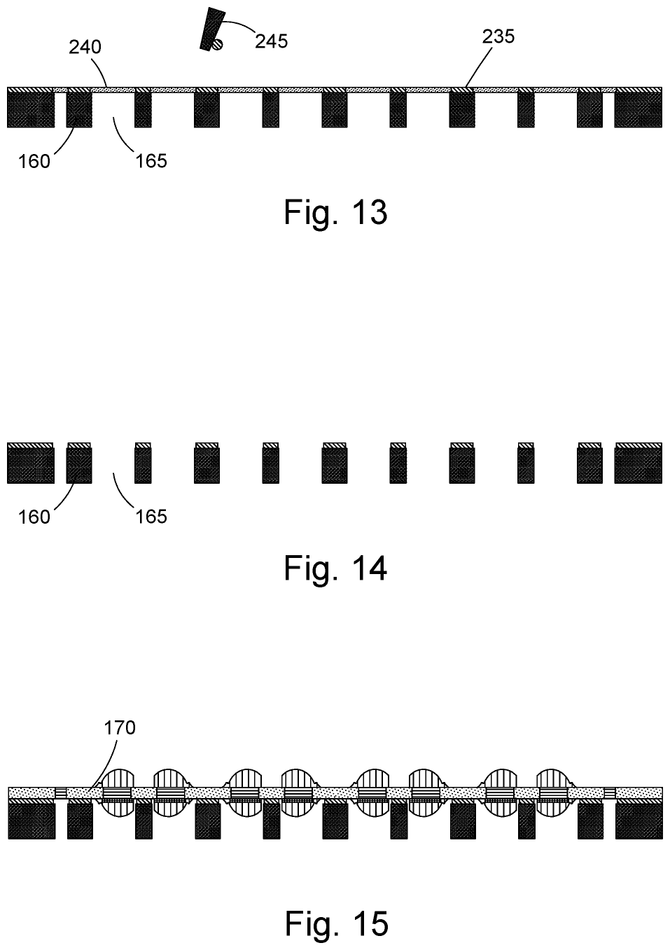

FIG. 13 depicts a process of applying an adhesive to an apertured substrate formed by a method according to an embodiment of the disclosure;

FIG. 14 depicts a cross-sectional view of the apertured substrate of FIG. 13 having an adhesive applied to one side;

FIG. 15 depicts steps in a process of assembling the optical package;

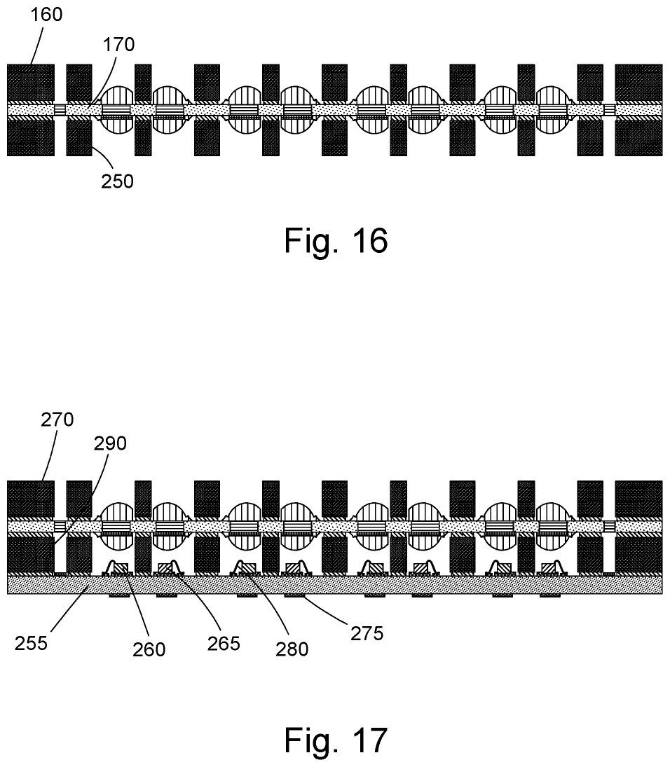

FIG. 16 depicts a cross-sectional view of an intermediate stage in the assembly of the optical package;

FIG. 17 depicts a cross-sectional view of an intermediate stage in the assembly of the optical package;

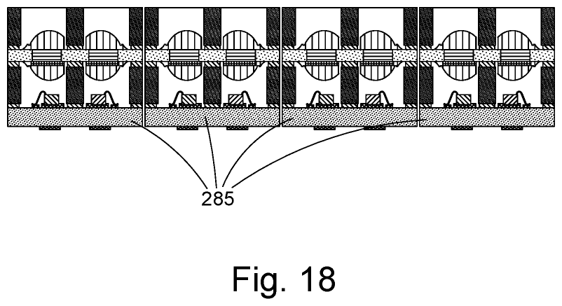

FIG. 18 depicts a cross-sectional view of the optical package after singulation;

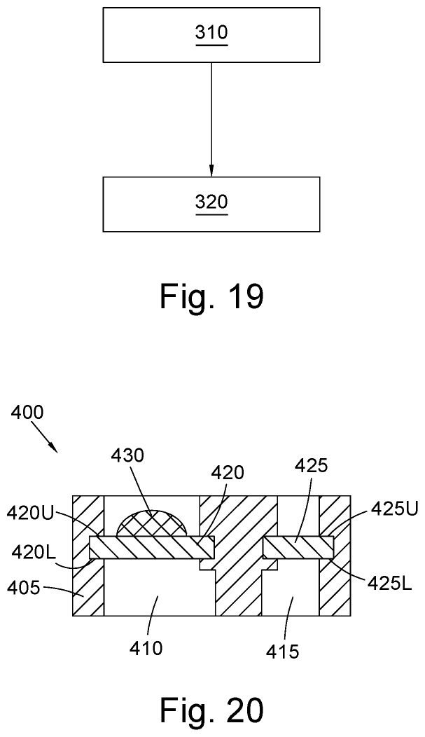

FIG. 19 depicts a flow-diagram corresponding to a method of wafer-level manufacturing of an optical package according to an embodiment of the disclosure;

FIG. 20 depicts a cross-sectional view of the optical package according to an embodiment of the disclosure;

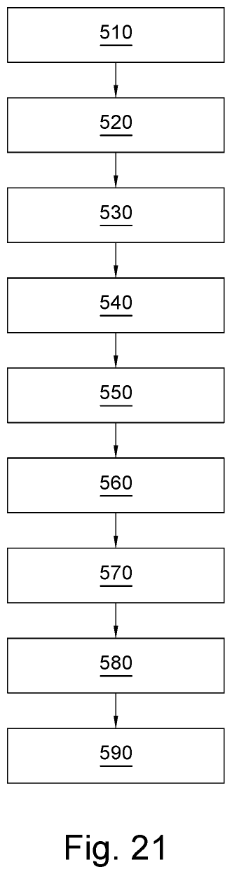

FIG. 21 depicts a flow-diagram corresponding to a method of wafer-level manufacturing of the optical package of FIG. 20; and

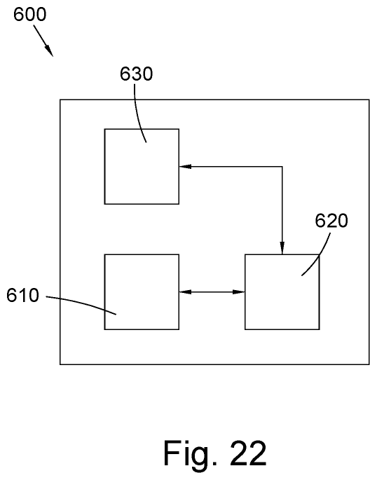

FIG. 22 depicts an apparatus according to an embodiment of the disclosure.

### DETAILED DESCRIPTION OF THE PREFERRED EMBODIMENTS

FIG. 1 depicts a representation of initial steps in a process of wafer-level manufacturing of an optical package, according to an embodiment of the disclosure. The steps described with respect to FIG. 1 relate to manufacture of an optical baffle, which may form a component of an assembled optical package 285.

Initially, an injection tool 105 is provided. In the example of FIG. 1, a cross-section of the injection tool 105 is depicted, wherein the injection tool 105 comprises a planar, relatively flat surface 110. The injection tool 105 may comprise polydimethylsiloxane (PDMS).

A film 115 is provided. The film may be a polyester film, such as a stretched polyethylene terephthalate (PET) film. The film may comprise biaxially-oriented polyethylene terephthalate (BoPET). Advantageously, the film may prevent adhesion of a mold compound 140 to the injection tool 105, thus facilitating easy removal of the mold compound 140 from the injection tool 105 without damaging a molded product, as described in more detail below.

Also depicted in FIG. 1 is a baffle tool 120. The baffle tool 120 comprises a pattern corresponding to a negative of a plurality of baffles to be manufactured according to the disclosed process. That is, the baffle tool 120 may be configured to be used as a mold in a vacuum injection molding process, as described below. The baffle tool 120 may comprise polydimethylsiloxane (PDMS).

The baffle tool 120 comprises a flat surface 125 having a plurality of protrusions 130. Spaces 135 between the protrusions 130 define a shape and size of baffles to be manufactured according to the disclosed process.

FIG. 2 depicts a representation of further steps in the process of wafer-level manufacturing of the optical package 285, according to an embodiment of the disclosure. In use, film 115 is disposed over the flat surface 110 of the injection tool 105. Next, the baffle tool 120 may be brought into contact with the film 115. In such an arrangement, the flat surface 110 of the injection tool 105 opposes the flat surface 125 of the baffle tool, and the spaces 135 between the protrusions 130 define one or more voids and/or channels. In such an arrangement, the injection tool 105 and the baffle tool 120 collectively define a mold.

The film may be provided with a plurality of holes 155A, 155B to enable passage of a flow of mold compound 140 and/or passage of a flow of fluid during a subsequent vacuum injection molding process. For example, the film may be provided with holes 155A, 155B arranged at sides of, the film 115, e.g. opposite sides of a perimeter of the film 115. In an example, a first hole 155A in the film may be for enabling a flow of mold compound 140 into the one or more voids or channels defined by the spaces 135 between the protrusions 130, and a second hole 155B in the film may enable a fluid to exit, e.g. be sucked, from the one or more voids or channels.

The injection tool 105 may be provided with a plurality of channels 150A, 150B for use in a vacuum injection molding process. For example, a first channel 150A defining an inlet in the injection tool 105 may be provided to enable a flow of mold compound 140 into the one or more voids or channels, and a second channel 150B defining an outlet in the injection tool 105 may enable a fluid to be sucked from the one or more voids or channels. That is, a relatively low pressure, e.g. a partial vacuum, may be provided at the second channel 150B to facilitate a flow of mold compound 140. Such relatively low pressure may also degas bubbles created in the mold compound 140 during such flow.

When the film 115 is disposed over the flat surface 110 of the injection tool 105, the holes 155A, 155B in the film 115 are aligned with the holes 150A, 150B in the injection tool 105.

Next, a mold compound 140 is vacuum injected into the one or more voids and/or channels defined by the spaces 135 between the protrusions 130.

The mold compound 140 may comprise an epoxy resin. The mold compound 140 may be optically opaque, e.g., black in color. The mold compound 140 may be opaque to wavelengths of radiation emitted by and/or sensed by the optical devices 260, 265.

Next, the mold compound 140 may be solidified by means of ultraviolet curing 145 and/or thermal curing 195. Beneficially the film 115 and/or the injection tool 105 and/or the baffle tool 120 is/are transparent to at least ultraviolet radiation, thus reducing a time required for curing the mold compound 140.

Next, the solidified mold compound 140, hereafter referred to as an apertured substrate 160, is removed from the mold, e.g. separated from the injection tool 105 and the baffle tool 120, and the film 115 is removed.

FIG. 3a depicts a cross-sectional view of an apertured substrate 160, i.e. a substrate comprising apertures, formed by the method described above. The apertured substrate 160 is suitable for use in providing baffles, e.g. optically opaque baffles, for use in optical packages 285 as described below in more detail.

FIG. 3b depicts a top view of the apertured substrate 160 of FIG. 3a. The apertured substrate 160 comprises a plurality of apertures 165, wherein the apertures are formed during the vacuum injection molding process by the patterns on the baffle tool 120.

It will be appreciated that the process described above with reference to FIGS. 1 and 2 may also be used with other tools to form other apertured substrates. For example, the process may be performed using a spacer tool (not shown) to form an apertured substrate suitable for use is providing spacers in optical packages 285, as described below in more detail.

The process describe above with reference to FIGS. 1 and 2 may be used to form an apertured substrate 170 as depicted in cross-section in FIG. 4a, wherein instead of using a baffle tool 120 to define baffles or a spacer tool to define spacers, a tool may instead be used to define apertures configured to support an optical element.

For example, the example apertured substrate 170 of FIG. 4a comprises a plurality of apertures 175A, 175B arranged in pairs. FIG. 4b depicts a top view of a portion of the apertured substrate 170, showing the pair of apertures 175A, 175B.

FIG. 5 depicts a representation of further steps in the process of wafer-level manufacturing of the optical package 285, according to an embodiment of the disclosure.

In FIG. 5, the apertured substrate 170 of FIG. 4a is attached to a flat mold 180. The flat mold 180 may be a PDMS mold.

Next, an epoxy 185 is jetted into the plurality of apertures 175A, 175B using a jetting tool 190. The epoxy 185 is transparent to wavelengths of radiation emitted or sensed by optical devices 260, 265 within the assembled optical package 285, as describe below in more detail.

Next, the epoxy 185 is solidified by means of ultraviolet and/or thermal curing.

It can be seen that the epoxy 185 may slightly overfill each aperture 175A, 175B. In the example of FIG. 5, the epoxy 185 forms a convex meniscus in each aperture 175A, 175B.

At a subsequent step after hardening of the epoxy 185, the apertured substrate 170 and/or the epoxy 185 may be ground and/or polished. After grinding and/or polishing, the epoxy 185 is flush with a surface of the apertured substrate 170, as depicted in FIG. 6a. Furthermore, the apertured substrate 170 comprising the epoxy 185 within its apertures may be ground and/or polished to a desired thickness and/or a target surface roughness.

As such, the hardened epoxy 180 forms optical elements 225 in the apertures of the apertured substrate 170. FIG. 6b depicts a top view of a pair of optical elements 225 formed from the hardened epoxy 180 in the apertures 175A, 175B of the apertured substrate 170.

FIG. 7 depicts a representation of optional further steps in the process of wafer-level manufacturing of the optical package 285, according to some embodiments of the disclosure. In FIG. 7, a layer of material 200 is deposited on a surface of the apertured substrate 170 such that a surface of the apertured substrate 170 including the optical elements 255 formed in the apertures is coated. The layer of material 200 may be a photoresist layer. The layer of material 200 may be deposited by a process of spin coating or spray coating to achieve a desired thickness. The layer of material 200 may, for example, comprise material suitable for optical filtering. For example, in some embodiments, the photoresist layer may comprise a material suitable for filtering infrared radiation.

A mask 205 and a radiation source 210 may be used to pattern the layer of material 200 by selectively exposing a portion of the layer of material 200 to the radiation source 210. As such, FIG. 8 depicts in cross section the apertured substrate 170 of FIG. 7, after a process of developing to leave a layer of photoresist material formed over each optical element.

It will be appreciated that FIG. 7 depicts an example only, and in embodiments, either a positive or negative photoresist and associated masks may be used.

In some embodiments, lenses 215 are formed over one or both sides of each of the optical elements 225. FIGS. 9 and 10 depict a process of forming lenses over one side of each of the optical elements 225.

In FIG. 9, a mold 220 having a pattern of cavities corresponding to a negative of a plurality of lenses 215 is provided. The mold 220 may be a PDMS mold. An epoxy 230 is jetted or otherwise deposited into the cavities.

As depicted in FIG. 10, the mold 220 and epoxy 230 are used to replicate lenses 215 over the optical elements 225. The lenses 215, which are formed from hardened epoxy 230, are transparent to wavelengths of radiation emitted by and/or sensed by the optical devices 260, 265.

The epoxy 230 may be solidified by means of ultraviolet and/or thermal curing, and then the mold 220 may be removed. The mold 220, and therefore the epoxy 230, may be pressed against the apertured substrate 170.

FIG. 11 depicts a cross-sectional view of an apertured substrate 170 having lenses 215 formed on one side of each optical element 225.

The process of forming lenses 215 described with reference to FIGS. 9 to 11 may be repeated to form lenses 215 on an opposite sides of each of the optical elements 225, as depicted in FIG. 12, which shows a cross-sectional view of an apertured substrate having lenses formed on both sides of each optical element. It will be appreciated that in some embodiments a different mold may be used to form lenses having different characteristics on each side of the optical elements 225.

FIGS. 13 to 17 describe a process of assembly of optical packages 285.

FIG. 13 depicts a process of applying an adhesive to an apertured substrate formed by a method according to an embodiment of the disclosure.

An adhesive 235 is applied using a dispenser such as a jetting tool 245 to an upper surface of the apertured substrate 160, e.g. the apertured substrate 160 defining the baffles. A mask 240 may be used to prevent adhesive 235 being deposited in and/or close to edges of the apertures 165 within the apertured substrate 160.

FIG. 14 depicts the apertured substrate 160 having the layer of adhesive 235 applied to a surface. In some embodiments, the mask 240 is used to ensure that the adhesive 235 does not extend to an edge of each aperture 165, thus minimizing a risk that adhesive 235 may leak or be forced into the apertures 165.

FIG. 15 depicts a further step in the process of assembling the optical package 285. The apertured substrate 160 comprising the layer of adhesive 235 is stacked on the apertured substrate 170 comprising the optical elements 225. Next, the adhesive 235 may be cured by means of ultraviolet curing and/or thermal curing.

As depicted in FIG. 16, the process described with respect to FIGS. 13, 14 and 15 may be repeated to stack one or more further layers. For example, an apertured substrate 150 defining spacers 290 may be stacked on an opposite side of the apertured substrate 170.

In FIG. 17, a further substrate 255 is provided. In the example of FIG. 17, the substrate 255 is a printed circuit board (PCB). Optical devices 260, 265 are mounted on an upper side of the further substrate 255. The optical devices 260, 265 may comprise, for example, radiation-sensitive devices and/or radiation-emitting devices. In one embodiment, an optical device 260 is a device configured to emit infrared radiation, and an optical device 265 is an optical device configured to sense infrared radiation. In some embodiments, the optical device 260 is a VCSEL.

A lower side of the further substrate 255 comprises electrical contacts 275. The electrical contacts 275 may be conductively coupled to the optical devices 260, 265 by vias extending through the further substrate 255. In some embodiments, bond wires 280 electrically couple to the optical devices 260, 265 to the further substrate 255.

The further substrate 255 may be coupled to the apertured substrate 250 using an adhesive, generally following the same processes as described above with reference to FIGS. 13 to 15, e.g. using a mask in some embodiments.

FIG. 18 depicts a cross-sectional view of assembled optical packages 285 after a process of singulation. The process of singulation comprises cutting, such as sawing with a dicing saw, the assembled apertured substrates 160, 170, 255 and further substrate 255, to provide a plurality of assembled optical packages 285.

The example assembled optical packages 285 comprise, in sequential order from an upper surface comprising apertures 165:
an apertured substrate 160 defining optical baffles 270;
an apertured substrate 170 configured to support a plurality of optical elements 225;
an apertured substrate 250 defining spacers; and
a further substrate 255, wherein optical devices 260, 265 are mounted on the further substrate 255.

FIG. 19 depicts a flow-diagram corresponding to the above-described method of wafer-level manufacturing of an optical package according to an embodiment of the disclosure.

The method comprises a step 310 of forming an apertured substrate by a process of vacuum injection molding, each aperture in the apertured substrate configured to support an optical element, e.g. optical element 225.

The method also comprises a step 320 of coupling the apertured substrate to a further substrate comprising optical devices aligned with the apertures in the apertured substrate.

In other embodiments of the disclosure, the process described above with reference to FIGS. 1 and 2 may be used with other tools to form other apertured substrates. For example, the process may be performed using a tool (not shown) to form an apertured substrate suitable for use in providing diffusers for use in optical packages.

In such a diffuser application, an apertured substrate may be attached to a film. As described above with reference to the example of manufacture of baffles in FIG. 1, the film may be provided with holes to enable a process of vacuum injection molding.

The apertured substrate together with the film may be disposed between an upper, substantially flat tool and a lower tool having holes corresponding to the holes in the film. Thus, the upper and lower tools collectively form a mold.

Subsequently, a transparent epoxy or other liquid adhesive may be injected into the mold with a relatively low pressure, e.g. a partial vacuum, supplied at an outlet of the mold to facilitate a flow of the transparent epoxy and to degas the bubbles created in the transparent epoxy during the flow. The transparent epoxy may be solidified by curing, such as by thermal and/or ultraviolet curing, and subsequently separated from the mold.

The apertured substrate may then be ground and/or polished to remove any excess epoxy.

The apertured substrate may then be ground and/or polished to remove achieve a desired thickness.

In some embodiments, the apertured substrate may be singulated into single diffuser units, which may be suitable for assembly into optical packages.

FIG. 20 depicts a cross-sectional view of an optical package 400 according to a further embodiment of the disclosure.

Manufacture of the optical package 400 comprises forming an apertured substrate 405 by a process of vacuum injection molding, each aperture 410, 415 in the apertured substrate 405 configured to support an optical element 420, 425.

Manufacture of the optical package 400 may also comprise coupling the apertured substrate 400 to a further substrate, for example a substrate 255 comprising optical devices 260, 265 aligned with the apertures 410, 415 in the apertured substrate 405. In the example of FIG. 21, one of the optical elements 420 comprises a lens 430, which may be formed according to the method described above with respect to FIGS. 9 to 11.

In the example embodiment of FIG. 20, each aperture 410, 415 is formed around a corresponding optical element 420, 425. That is, the apertured substrate 405 is formed on a portion of an upper surface 420U, 425U and a portion of a lower surface 420L, 425L of each optical element 420, 425, such that the optical element 420, 425 is retained by the apertured substrate 405.

The apertured substrate 405 effectively forms a frame configured to hold the each optical element 420, 425, the frame arranged around at least a portion of a perimeter of each optical element 420, 425. That is, the apertured substrate 405 is configured to both support the optical element 420, 425 and provide the functionality of an optical baffle and/or spacer.

A method of manufacture of the optical package 400 of FIG. 20 is described in more detail with reference to the flow diagram of FIG. 21.

In an optional first step 510, a substrate such as a glass substrate is prepared. Preparation of the substrate may comprise cleaning and/or polishing. Preparation of the substrate may comprise deposition of one or more films or layers of material. For example, preparation of the substrate may comprises deposition of layers to form a filter, e.g. an interference filter such as a band-pass filter.

In a second step 520, the substrate is singulated, e.g. diced, to provide a plurality of optical elements 420, 425.

Optional third fifth steps 530, 540, 550 describe a process of forming a lens on each optical element 420, 425. It will be appreciated that lens may be formed on one surface or both upper and lower surfaces of each optical element 420, 425. Furthermore, lenses may be formed on some or all of the optical elements 420, 425, depending upon particular application requirements. It can be seen in the example embodiment of FIG. 20 that only one optical element 420 has a single lens 430 formed on an upper surface.

In a third step 530, the diced optical elements 420, 425 are arranged on a mold, such as a PDMS mold. At a fourth step 540, lenses 530 are then formed on some or all of the optical elements 420, 425 using a process of jetting and replication using an epoxy. The process of jetting and replication using an epoxy may correspond to the process described above with reference to FIGS. 9 to 11, except the individual diced optical elements 420, 425 are located on a mold.

At a fifth step 550, the epoxy forming the lenses 530 is cured, by thermal and/or ultraviolet curing.

At a sixth step 560, the diced optical elements 420, 425 may be separated from the mold.

At a seventh step 570, the diced optical elements 420, 425 may be arranged and aligned relative to a mold and/or spacer tool, e.g. a tool having a negative of a spacer.

At an eight step 580, a process of vacuum injection molding is used to form the apertured substrate 405. A mold compound, which may be an optically opaque epoxy, is injected into the mold and/or spacer tool to form the apertured substrate 405. As described above with reference to FIG. 2, a relatively low pressure, e.g. a partial vacuum, may be provided to facilitate a flow of the mold compound and to degas bubbles created in the mold compound.

At a ninth step 590, the mold compound may be cured by means of ultraviolet and/or thermal cure, such that the mold compound is solidified.

Subsequent steps may comprise separating the apertured substrate 405 from the mold. The apertured substrate may be mounted on a dicing tape prior to a subsequent process of singulation into individual optical packages 400. In some embodiments a process of optical inspection may be used to determine individual optical packages 400 of sufficient quality for subsequent assembly with a further substrate, e.g. a substrate 255 such as that of FIG. 18 comprising one or more optical devices 260, 265.

FIG. 22 depicts an apparatus 600 according to an embodiment of the disclosure. The apparatus 600 may be one of: a smartphone; a cellular telephone; a tablet; or a laptop device.

The apparatus 600 comprises an optical package 610 according to an embodiment of the disclosure. The optical package 610 may be an optical package 285, 400 as described above with reference to FIGS. 19 and 21 respectively. In the example embodiment of FIG. 22, the optical package 610 is coupled to a processor 620. The processor may be configured to control a radiation-emitting device and/or receive data or and/or a signal from a radiation-sensing device in the optical package 610.

The example apparatus 600 also comprises a camera 630. In some embodiments, the processor 620 may be configured to adjust one or more properties of the camera 630, or an image captured by the camera 630, based upon the data or and/or signal received from the radiation-sensing device in the optical package 610.

For example, the optical package 610 may be configured as a proximity sensor or a time-of-flight sensor. The processor may determine a proximity of a target to be imaged by the camera 630 from the data or and/or signal received from the radiation-sensing device in the optical package 610, and may adjust a focus of the camera 630 in response.

Although the disclosure has been described in terms of particular embodiments as set forth above, it should be understood that these embodiments are illustrative only and that the claims are not limited to those embodiments. Those skilled in the art will be able to make modifications and alternatives in view of the disclosure, which are contemplated as falling within the scope of the appended claims. Each feature disclosed or illustrated in the present specification may be incorporated in any embodiments, whether alone or in any appropriate combination with any other feature disclosed or illustrated herein.

LIST OF REFERENCE NUMERALS

| | |
|---|---|
| 105 | injection tool |
| 110 | flat surface |
| 115 | film |
| 120 | baffle tool |
| 125 | flat surface |
| 130 | protrusions |
| 135 | spaces |
| 140 | mold compound |
| 145 | ultraviolet curing |
| 150A | first channel |
| 150B | second channel |
| 155A | first hole |
| 155B | second hole |
| 160 | apertured substrate |
| 165 | apertures |
| 170 | apertured substrate |
| 175A | aperture |
| 175B | aperture |
| 180 | flat mold |
| 185 | epoxy |
| 190 | jetting tool |
| 195 | thermal curing |
| 200 | layer of material |
| 205 | mask |
| 210 | radiation source |
| 215 | lenses |
| 220 | mold |
| 225 | optical elements |
| 230 | epoxy |
| 235 | adhesive |
| 240 | mask |
| 245 | jetting tool |
| 250 | apertured substrate |
| 255 | further substrate |
| 260 | optical device |
| 265 | optical device |
| 270 | baffle |
| 275 | electrical contacts |
| 280 | bond wires |
| 285 | optical package |
| 290 | spacer |
| 310 | step |
| 320 | step |
| 400 | optical package |
| 405 | apertured substrate |
| 410 | aperture |
| 415 | aperture |
| 420 | optical element |
| 420U | upper surface |
| 420L | lower surface |
| 425 | optical element |
| 425U | upper element |
| 425L | lower element |
| 430 | lens |
| 510 | first step |
| 520 | second step |
| 530 | third step |
| 540 | fourth step |
| 550 | fifth step |
| 560 | sixth step |
| 570 | seventh step |
| 580 | eighth step |
| 590 | ninth step |
| 600 | apparatus |
| 610 | optical package |
| 620 | processor |
| 630 | camera |

1. A method of wafer-level manufacturing of an optical package (285), the method comprising:
forming an apertured substrate (170; 405) by a process of vacuum injection molding, each aperture (175A; 175B) in the apertured substrate configured to support an optical element (225; 420; 425); and
coupling the apertured substrate to a further substrate (255) comprising optical devices (260; 265) aligned with the apertures in the apertured substrate.

2. The method of claim 1, comprising a step of forming an optical element (225; 420; 425) in each aperture (175A; 175B) by jetting or molding an epoxy (230) into each aperture, the epoxy transparent to radiation emitted and/or sensed by the optical devices (260; 265).

3. The method of claim 2, further comprising at least one of:
curing the epoxy (230); and/or
grinding and/or polishing the epoxy after hardening of the epoxy.

4. The method of claim 1, comprising a step of forming at least one layer of material (200) over the optical element (225; 420; 425), the at least one layer of material configured as:
a filter;
a polarizer;
an anti-reflective coating; and/or
a diffuser.

5. The method of claim 1, comprising adhering or forming a lens (215) over one or both sides of the optical element (225; 420; 425).

6. The method of claim 5, wherein the lens (215) is formed by a process of replication.

7. The method of claim 1, wherein each aperture (175A; 175B) is formed around the optical element.

8. The method of claim 7, wherein the apertured substrate (170) is formed on a portion of an upper and a lower surface of the optical element (225; 420; 425), such that the optical element is retained by the apertured substrate.

9. The method of claim 7, wherein the apertured substrate (170) forms a frame configured to hold the optical element (225; 420; 425), the frame arranged around at least a portion of a perimeter of the optical element.

10. The method of claim 1, wherein the apertured substrate (170) is formed to comprise at least one of:
an optical baffle;
a spacer; and/or
a cap structure.

11. The method of claim 1, comprising at least one step of:
forming a further apertured substrate (160; 250) having apertures configured for baffles and/or spacers; and
adhering the further apertured substrate to the apertured substrate (170) such that apertures in both substrates are aligned.

12. The method of claim 1, comprising a step of singulating the apertured substrate (170) and the further substrate (225; 420; 425) after the apertured substrate has been coupled to the further substrate (255), to provide a plurality of optical packages (285; 600), each optical package comprising at least one optical device (260; 265) and at least one optical element (225; 420; 425).

13. An optical package (285; 600) formed according to the method of claim 1.

14. The optical package of claim 13, wherein the optical devices (260; 265) comprise:
a device configurable to emit infrared radiation; and/or
a radiation-sensitive device configurable to sense infrared radiation.

15. An apparatus (600) comprising the optical package according to claim 13, wherein the apparatus is one of: a smartphone; a cellular telephone; a tablet; or a laptop device.
